(19) United States
(12) Patent Application Publication
(10) Pub. No.: US 2024/0096720 A1
(43) Pub. Date: Mar. 21, 2024

(54) Semiconductor module having a double-sided heat dissipation structure and A Method for fabricating the same

(71) Applicant: LX SEMICON CO., LTD., Daejeon (KR)

(72) Inventors: Deog Soo KIM, Daejeon (KR); Tae Ryong KIM, Daejeon (KR)

(73) Assignee: LX SEMICON CO., LTD., Daejeon (KR)

(21) Appl. No.: 18/512,939

(22) Filed: Nov. 17, 2023

(30) Foreign Application Priority Data
Sep. 20, 2022 (KR) 10-2022-0118827

(51) Int. Cl. H01L 23/24; H01L 21/48; H01L 23/00; H01L 23/373; H01L 25/00; H01L 25/07

(52) U.S. Cl. CPC H01L 23/24; H01L 21/4803; H01L 23/3735; H01L 24/05; H01L 24/06; H01L 24/29; H01L 24/32; H01L 24/33; H01L 24/83; H01L 25/072; H01L 25/50; H01L 2224/05624; H01L 2224/05639; H01L 2224/05655; H01L 2224/05666; H01L 2224/05672; H01L 2224/0603; H01L 2224/06181; H01L 2224/06505; H01L 2224/29111; H01L 2224/29139; H01L 2224/32225; H01L 2224/3303; H01L 2224/33181; H01L 2224/8314; H01L 2224/83192; H01L 2924/0132; H01L 2924/10272; H01L 2924/13055; H01L 2924/13091

(57) ABSTRACT

A semiconductor module having a double-sided heat dissipation structure according to one aspect of the present invention, which can secure the gap between the first and second heat dissipation substrates without using existing spacers, includes a first heat dissipation substrate and a second heat dissipation substrate arranged to face each other; a guide stack disposed between the first heat dissipation substrate and the second heat dissipation substrate, and having an opening area for mounting a semiconductor die in a pattern; and a semiconductor die mounted within the opening area.

### CROSS-REFERENCE TO RELATED APPLICATIONS

The present application claims the benefits of priority to Korean Patent Application No. 10-2022-0118827, filed on Sep. 20, 2022, which is incorporated herein by reference in its entirety.

### TECHNICAL FIELD

The present invention relates to a semiconductor module, and more specifically, to a semiconductor module having a double-sided heat dissipation structure.

### BACKGROUND

Recently, as demand for semiconductors has increased in various fields, various research and developments are being conducted to improve semiconductor functions under specific conditions in addition to the main functions of semiconductors.

In general, a semiconductor module may include at least one semiconductor device in one package. In particular, in the case of a semiconductor module containing a semiconductor device whose physical properties may change due to an increase in heat generation due to high internal voltage and high current, a heat dissipation means may be included to dissipate heat. The semiconductor modules including a heat dissipation means can be divided into a semiconductor module with a single-sided heat dissipation structure and a semiconductor module with a double-sided heat dissipation structure.

In particular, the semiconductor modules with a double-sided heat dissipation structure are known to be advantageous in terms of heat dissipation effectiveness because they can dissipate heat to both the top and bottom of each semiconductor device.

Since the semiconductor module with the double-sided heat dissipation structure requires the semiconductor devices to be individually mounted on a heat dissipation board, thickness deviation may occur between the semiconductor device and the heat dissipation board. Due to this thickness deviation, not only can poor adhesion between the semiconductor device and the heat dissipation substrate occur, but there is also a problem that process control is difficult when manufacturing the semiconductor module.

### SUMMARY

The present invention is intended to solve the above-mentioned problems, and its technical object is to provide a semiconductor module with a double-sided heat dissipation structure that can secure the gap between first and second heat dissipation substrates and a manufacturing method thereof.

In addition, another technical object of the present invention is to provide a semiconductor module with a double-sided heat dissipation structure that can manufacture a plurality of semiconductor dies as one assembly and couple them to the first and second heat dissipation substrates, and a method of manufacturing the same.

A semiconductor module having a double-sided heat dissipation structure according to an aspect of the present invention for achieving the above-described object includes a first heat dissipation substrate and a second heat dissipation substrate arranged to face each other; a guide stack disposed between the first heat dissipation substrate and the second heat dissipation substrate, and having an opening area for mounting a semiconductor die in a pattern; and a semiconductor die mounted within the opening area.

In addition, a method of manufacturing a semiconductor module with a double-sided heat dissipation structure according to another aspect of the present invention includes manufacturing a guide assembly by forming a guide stack with an opening area for mounting a semiconductor die on a base plate; coupling a second surface of the base plate to a first heat dissipation substrate; mounting the semiconductor die on a first surface of the base plate corresponding to the opening area; and coupling a second heat dissipation substrate on the semiconductor die and the guide stack.

In addition, a method of manufacturing a semiconductor module with a double-sided heat dissipation structure according to another aspect of the present invention includes forming a guide stack with an opening area for mounting a semiconductor die on a first heat dissipation substrate; mounting the semiconductor die on an area of the first heat dissipation substrate exposed by the opening area; and coupling a second heat dissipation substrate on the semiconductor die and the guide stack.

According to the present invention, since one guide assembly capable of mounting a plurality of semiconductor dies only needs to be coupled between the first and second heat dissipation substrates, thickness deviation between the semiconductor die and the heat dissipation substrate can be prevented. There is an effect that process control becomes easier when manufacturing a semiconductor module with a double-sided heat dissipation structure.

In addition, according to the present invention, since a plurality of semiconductor dies are mounted on one guide assembly, flatness can be improved when combined with the first and second heat dissipation substrates, which has the effect of improving yield.

In addition, according to the present invention, since a plurality of semiconductor dies are mounted in the opening area formed in the guide stack, it is possible to prevent the semiconductor die from being damaged during a high-temperature pressure sintering process.

### BRIEF DESCRIPTION OF THE DRAWINGS

The accompanying drawings, which are incorporated herein and form part of the specification, illustrate various, non-limiting embodiments of the present invention. In the drawings, like reference numbers indicate identical or functionally similar elements.

FIG. 1 is a diagram schematically showing the configuration of a semiconductor module with a double-sided heat dissipation structure according to the first embodiment of the present invention.

FIG. 2 is a diagram schematically showing the configuration of the semiconductor die shown in FIG. 1.

FIG. 3 is a diagram showing the schematic configuration of the guide assembly shown in FIG. 1.

FIG. 4 is a diagram schematically showing the configuration of a semiconductor module with a double-sided heat dissipation structure according to a second embodiment of the present invention.

FIG. 5 is a schematic circuit diagram of a power device using a semiconductor module with a double-sided heat dissipation structure according to an embodiment of the present invention.

FIGS. 6A to 6F are schematic process cross-sectional views showing a method of manufacturing a semiconductor module with a double-sided heat dissipation structure according to the first embodiment of the present invention.

FIGS. 7A to 7E are schematic process cross-sectional views showing a method of manufacturing a semiconductor module with a double-sided heat dissipation structure according to a second embodiment of the present invention.

### DETAILED DESCRIPTION

Throughout the specification, identical reference numbers refer to substantially identical elements. In the following description, detailed descriptions of configurations and functions known in the technical field of the present invention and cases not related to the core configuration of the present invention may be omitted. The meaning of terms described in this specification should be understood as follows.

The advantages and features of the present invention and methods for achieving them will become clear by referring to the embodiments described in detail below along with the accompanying drawings. However, the present invention is not limited to the embodiments disclosed below and will be implemented in various different forms and only the present embodiments ensure that the disclosure of the present invention is complete. In addition, the present invention is provided to fully inform those skilled in the art of the present invention of the scope of the invention, and the present invention is only defined by the scope of the claims.

The shape, size, ratio, angle, number, etc. disclosed in the drawings for explaining embodiments of the present invention are illustrative, and the present invention is not limited to the matters shown. Identical reference signs refer to identical elements throughout the specification. Additionally, in describing the present invention, if it is determined that a detailed description of related known technologies may unnecessarily obscure the gist of the present invention, the detailed description will be omitted.

When ‘includes’, ‘has’, ‘consists of’, etc. mentioned in this specification are used, other parts may be added unless ‘only’ is used. When a component is expressed in the singular, the plural is included unless specifically stated otherwise.

When interpreting components, they are interpreted to include the margin of error even if there is no separate explicit description.

In the case of a description of a positional relationship, for example, when the positional relationship between two parts is described as ‘on top’, ‘on the top’, ‘on the bottom’, ‘next to’, etc. Unless ‘immediately’ or ‘directly’ is used, one or more other parts may be placed between the two parts.

In the case of a description of a temporal relationship, for example, if a temporal relationship is described as ‘after’, ‘following’, ‘before’, etc., ‘immediately’ or Non-consecutive cases can also be included unless ‘directly’ is used.

First, second, etc. are used to describe various components, but these components are not limited by these terms. These terms are merely used to distinguish one component from another. Accordingly, the first component mentioned below may also be the second component within the technical spirit of the present invention.

The term “at least one” should be understood to include all possible combinations from one or more related items. For example, “at least one of the first, second, and third items” means each of the first, second, or third items, as well as any combination of items that can be presented from two or more of the first, second, and third items.

Each feature of the various embodiments of the present invention can be partially or fully combined or combined with each other, various technical interconnections and operations are possible, and each embodiment may be implemented independently of each other or may be implemented together in a related relationship.

Hereinafter, embodiments of the present specification will be described in detail with reference to the attached drawings.

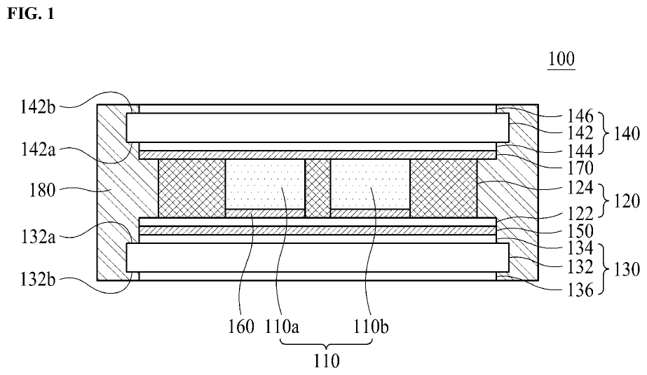

FIG. 1 is a diagram schematically showing the configuration of a semiconductor module with a double-sided heat dissipation structure according to a first embodiment of the present invention. As shown in FIG. 1, a semiconductor module 100 having a double-sided heat dissipation structure according to the first embodiment of the present invention (hereinafter referred to as ‘semiconductor module’) includes at least one semiconductor die 110 and a guide assembly 120, a first heat dissipation substrate 130, and a second heat dissipation substrate 140.

The semiconductor die 110 refers to a semiconductor device manufactured through a wafer-level process. In one embodiment, the semiconductor device included in the semiconductor die 110 may be a power semiconductor device. The power semiconductor device can convert power supplied from a power supply such as a battery into power for driving a motor through a switching operation and supply it.

As an example, the semiconductor die 110 may include a power semiconductor device such as a Gate Turn-Off thyristor (GTO), an Insulated Gate Bipolar Transistor (IGBT), or a Metal Oxide Semiconductor Field Effect Transistor (MOSFET), or a semiconductor device such a diode.

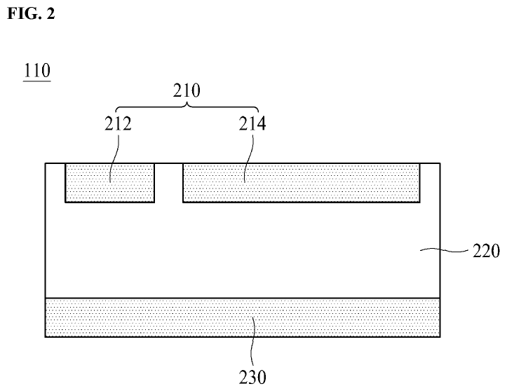

FIG. 2 is a diagram schematically showing the configuration of the semiconductor die according to an embodiment of the present invention. As shown in FIG. 2, the semiconductor die 110 according to an embodiment of the present invention may include a first electrode 210, a semiconductor layer 220, and a second electrode 230.

The first electrode 210 may be disposed on the semiconductor layer 220. In one embodiment, when the semiconductor die 110 may include a power semiconductor device such as a MOSFET, the first electrode 210 may include a gate electrode 212 and a source electrode 214. At this time, the gate electrode 212 and the source electrode 214 are formed to be electrically isolated from each other. As another example, when the semiconductor die 110 may include a power semiconductor device such as an IGBT, the first electrode 210 may include a gate electrode 212 and an emitter electrode 214. At this time, the gate electrode 212 and the emitter electrode 214 are formed to be electrically isolated from each other.

The second electrode 230 may be disposed below the semiconductor layer 220. In one embodiment, when the semiconductor die 110 may include a power semiconductor device such as a MOSFET, the second electrode 230 may include a drain electrode. As another example, when the semiconductor die 110 may include a power semiconductor device such as an IGBT, the second electrode 230 may include a collector electrode.

In the above-described embodiment, the first electrode 210 may be made of Al-based metal, and the second electrode 230 may be composed of Ti/Ni/Ag metal including a Ti layer, a Ni layer, and an Ag layer or NiV/Ag, V(vanadium)/Ni/Ag, etc., and the semiconductor layer 220 may include SiC (Silicon Carbide).

In one embodiment, the semiconductor dies 110 may all include the same type of semiconductor device. As another example, some of the semiconductor dies 110 may be implemented with other types of semiconductor devices.

The semiconductor die 110 as described above may be mounted between the first heat dissipation substrate 130 and the second heat dissipation substrate 140 through the guide assembly 120. At this time, a first semiconductor die 110a may be arranged so that the first electrode 210 faces the second heat dissipation substrate 140 and the second electrode 230 faces the first heat dissipation substrate 130. Additionally, a second semiconductor die 110b may be arranged such that the first electrode 210 faces the first heat dissipation substrate 130 and the second electrode 230 faces the second heat dissipation substrate 140.

Through this arrangement, the first electrode 210 of the first semiconductor die 110a and the second electrode 230 of the second semiconductor die 110b may be electrically connected to connect the first and second semiconductor die 110a and 110b to each other in series.

In another embodiment, each semiconductor die 110 may be disposed between the first and second heat dissipation substrates 120 and 130 so that all the same electrodes face the same direction. For example, the first electrodes 210 of the first and second semiconductor dies 110a to 110b may be arranged to all face toward the second heat dissipation substrate 140, and the second electrodes 230 of the first and second semiconductor dies 110a to 110b may be arranged to all face toward the first heat dissipation substrate 130. As another example, the first electrodes 210 of the first and second semiconductor dies 110a to 110b may be arranged to all face toward the first heat dissipation substrate 130, and the second electrodes 210 of the first and second semiconductor dies 110a to 110b may be arranged to all face toward the first heat dissipation substrate 130.

In FIG. 1, the semiconductor module 100 is shown as including two semiconductor dies 110a to 110b, but this is only an example, and the number of semiconductor dies 110 may vary depending on the type of application in which the semiconductor module 100 is used. As an example, the semiconductor module 100 may include eight semiconductor dies 110, and in this case, the eight semiconductor dies 110 may be arranged in a 4*2 matrix.

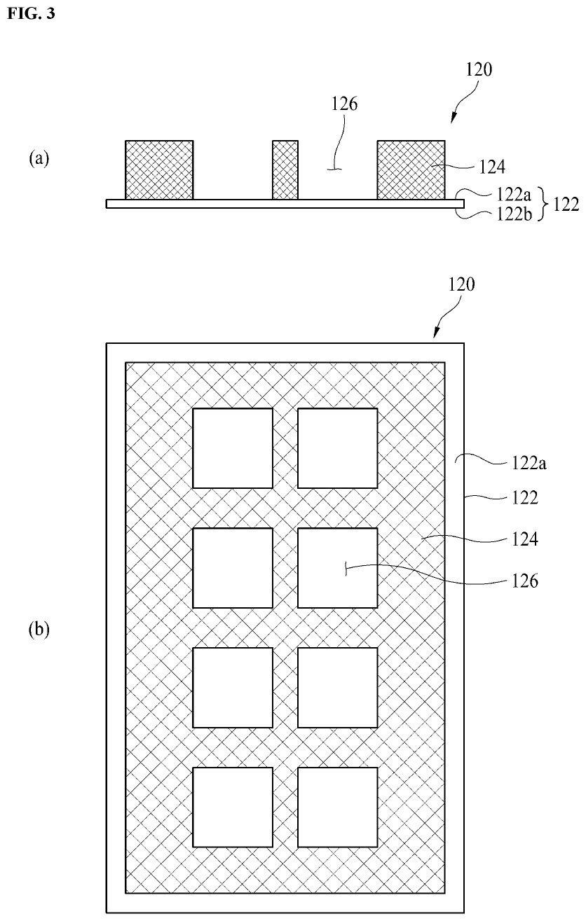

The semiconductor die 110 may be mounted on the guide assembly 120. Hereinafter, the configuration of the guide assembly 120 according to the present invention will be described in more detail with additional reference to FIG. 3. FIG. 3 (a) is a cross-sectional view of the guide assembly according to an embodiment of the present invention, and FIG. 3 (b) is a plan view of the guide assembly according to an embodiment of the present invention.

As shown in FIGS. 1 and 3, the guide assembly 120 may include a base plate 122 and a guide stack 124.

The base plate 122 may support the guide stack 124. The guide stack 124 may be formed on a first surface 122a of the base plate 122. A second surface 122b of the base plate 122 may be coupled to the first heat dissipation substrate 130 through a first adhesive member 150. The semiconductor die 110 may be mounted on an area of the base plate 122 exposed through an opening area 126 formed in the guide stack 124.

In one embodiment, the base plate 122 may be formed using a copper-based material, and circuit wiring of a predetermined pattern may be patterned on the base plate 122.

The first adhesive member 150 may couple the base plate 122 and the first heat dissipation substrate 130. In one embodiment, the first adhesive member 150 may be made of a conductive material, for example, a Sn—Ag series or Ag series material.

The guide stack 124 may be formed on the first surface 122a of the base plate 122, and a pattern may be formed in the opening area 126 for mounting the semiconductor die 110. In one embodiment, the number of opening areas 126 formed in the guide stack 124 may be the same as the number of semiconductor dies 110 included in the semiconductor module 100. For example, when the semiconductor module 100 may include six semiconductor dies, as shown in FIG. 3B, six opening areas 126 may be formed in the guide stack 124 to mount the six semiconductor dies.

A second adhesive member 160 may be formed in the area of the base plate 122 exposed through the opening area 126 of the guide stack 124, and within the opening area 126, the semiconductor die 110 may be coupled to the first surface 122a of the base plate 122 through the second adhesive member 160. The second adhesive member 160 may also be formed of the same conductive material as the first adhesive member 150. For example, the second adhesive member 160 may be made of Sn—Ag series or Ag series material.

In one embodiment, the guide stack 124 may be formed of EMC (Epoxy Mold Compound) or Fiber Glass. When the guide stack 124 may be formed of EMC, the guide stack 124 may be formed on the base plate 122 through a molding process using a mold. When the guide stack 124 is made of Glass Fiber, the guide stack 124 may be formed on the base plate 122 using a print screen technique.

Meanwhile, although not shown in the drawing, the opening area (not shown) may be additionally formed in the guide stack 124 to expose a lead frame terminal for electrically connecting the semiconductor die 110 to an external device.

In this way, according to the present invention, it is only necessary to couple the guide assembly 120 to the first heat dissipation substrate 130 and then mount the plurality of semiconductor dies 110 in the opening area 126 of the guide assembly 120, not only does it become easier to align the semiconductor dies 110, but also process control becomes easier when manufacturing a semiconductor module.

Additionally, according to the present invention, since a plurality of semiconductor dies may be mounted on one guide assembly, flatness can be improved when combined with the first and second heat dissipation substrates, thereby improving yield.

In addition, according to the present invention, since a plurality of semiconductor dies may be mounted in the opening area formed in the guide stack, damage to the semiconductor die during a high-temperature pressure sintering process can be prevented.

Referring again to FIG. 1, the first heat dissipation substrate 130 may radiate heat generated in the semiconductor die 110 to the outside of the first heat dissipation substrate 130.

The first heat dissipation substrate 130 may include a first substrate 132, a first metal wiring layer 134, and a first heat dissipation metal layer 136.

The first substrate 132 may electrically insulate the first metal wiring layer 134 and the first heat dissipation metal layer 136. The first substrate 132 may include a ceramic material with high thermal conductivity.

The first metal wiring layer 134 may be formed on the first surface 132a of the first substrate 132 facing the second heat dissipation substrate 140. The first metal wiring layer 134 may be formed with a predetermined circuit wiring pattern. In one embodiment, circuit wiring having the same pattern as the circuit wiring formed on the base plate 122 of the guide assembly 120 may be formed on the first metal wiring layer 134.

At this time, the first metal wiring layer 134 may be coupled to the second surface 122b of the base plate 122 included in the guide assembly 120 through the first adhesive member 150.

One side of the first heat dissipation metal layer 136 may be bonded to the second side 132b of the first substrate 132, and dissipates heat through the other side. A heat dissipation means including a cooling medium may be disposed close to the other surface of the first heat dissipation metal layer 136.

The second heat dissipation substrate 140 may radiate heat generated from the semiconductor die 110 to the outside of the second heat dissipation substrate 140.

The second heat dissipation substrate 140 may include a second substrate 142, a second metal wiring layer 144, and a second heat dissipation metal layer 146.

The second substrate 142 may electrically insulate the second metal wiring layer 144 and the second heat dissipation metal layer 146. The second substrate 142 may include a ceramic material with high thermal conductivity.

The second metal wiring layer 144 may be formed on the first surface 142a of the second substrate 142 facing the first heat dissipation substrate 130. The second metal wiring layer 144 may be formed with a predetermined circuit wiring pattern. The second metal wiring layer 144 may be coupled to the semiconductor die 110 and the guide stack 124 through a third adhesive member 170. In one embodiment, the third adhesive member 170 may be formed of a conductive material. For example, the third adhesive member 170 may be made of Sn—Ag series or Ag series material.

One side of the second heat dissipation metal layer 146 may be bonded to a second side 142b of the second substrate 142, and may dissipate heat through the other side. A heat dissipation means including a cooling medium may be disposed close to the other surface of the second heat dissipation metal layer 146.

In the above-described embodiment, the first and second metal wiring layers 134 and 144 and the first and second heat dissipation metal layers 136 and 146 may be made of copper-based metal. According to this embodiment, the first and second heat dissipation substrates 130 and 140 may be formed using any one of the Direct Bonded Copper (DBC) method, the Active Material Brazing (AMB) method, and the Direct Plating Copper (DPC) method.

In one embodiment, the space between the first heat dissipation substrate 130 and the second heat dissipation substrate 140 may be filled with a molding member 180. The molding member 180 may be EMC. The molding member 180 can increase the insulation distance between the first and second heat dissipation substrates 130 and 140, can protect the semiconductor die 110 from oxidation materials, and can perform the function of fixing the semiconductor die 110.

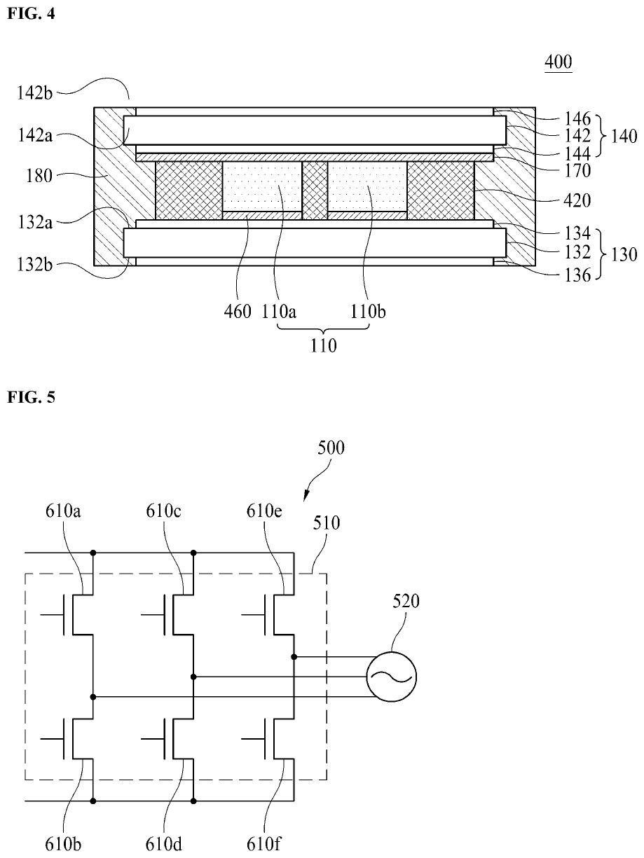

FIG. 4 is a diagram schematically showing the configuration of a semiconductor module with a double-sided heat dissipation structure according to a second embodiment of the present invention. As shown in FIG. 4, the semiconductor module 400 having a double-sided heat dissipation structure according to the second embodiment of the present invention may include a semiconductor die 110, a guide stack 420, a first heat dissipation substrate 130, and a second heat dissipation substrate 140.

The semiconductor module 400 according to the second embodiment shown in FIG. 4 may be the same as the semiconductor module 400 according to the first embodiment shown in FIG. 1 except that the guide stack 420 is not formed on the base plate 122, but directly on the first metal wiring layer 134 of the first heat dissipation substrate 130. Therefore, for convenience of explanation, hereinafter, only the differences that arise due to the guide stack 420 being formed on the first metal wiring layer 134 will be described.

In the case of the semiconductor module 400 according to the second embodiment, since the semiconductor module 400 according to the second embodiment does not include the base plate 122, the guide stack 420 may be formed directly on the first metal wiring layer 134 of the first heat dissipation substrate 130, and the semiconductor die 110 may be coupled to the first metal wiring layer 134 through the second adhesive member 460 formed in an area of the first metal wiring layer 134 exposed by the opening area.

In one embodiment, the guide stack 420 may be formed of EMC or Glass Fiber. When the guide stack 420 is formed of EMC, the guide stack 420 can be formed on the first metal wiring layer 134 through a molding process using a mold. When the guide stack 420 is made of Glass Fiber, the guide stack 420 can be formed on the first metal wiring layer 134 using a print screen technique.

FIG. 5 is a schematic circuit diagram of a power device to which the semiconductor module having a double-sided heat dissipation structure shown in FIGS. 1 and 4 is applied. As shown in FIG. 5, a power device 500 may include an inverter 510 and a motor 520.

The inverter 510 may supply AC power to the motor 520. The inverter 510 can receive DC (Direct Current) power from a battery or fuel cell, convert it into AC power, and then output the converted AC power to the motor 520. As shown in FIG. 5, the inverter 510 may include six semiconductor dies 610a to 610f Here, by configuring the semiconductor modules 100 and 400 according to FIGS. 1 and 4 to include six semiconductor dies, the semiconductor modules 100 and 400 according to the present invention perform the function of the inverter 510 of the power device 500.

The motor 520 may provide power to electric vehicles, fuel cell vehicles, etc. The motor 520 may be driven by receiving three-phase AC (Alternating Current) power.

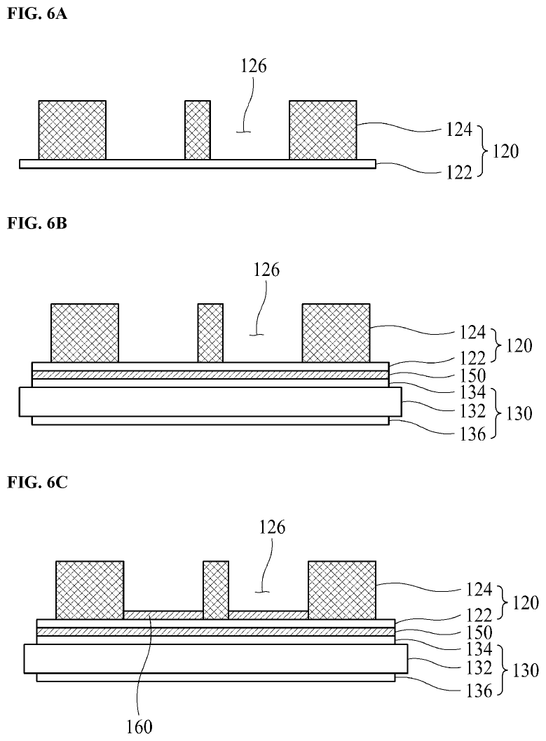

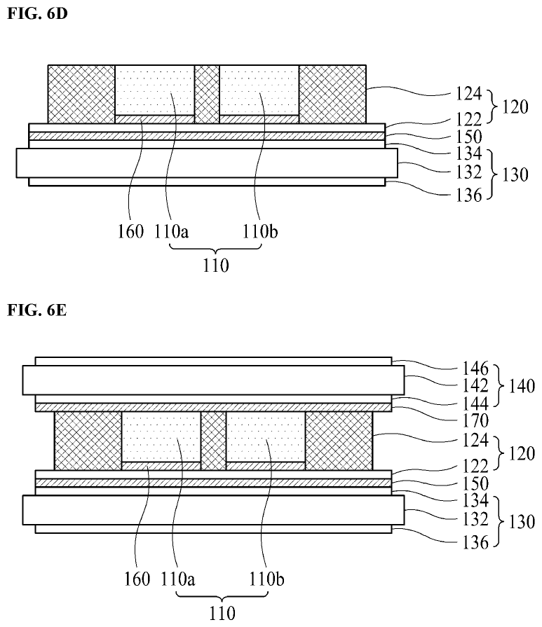

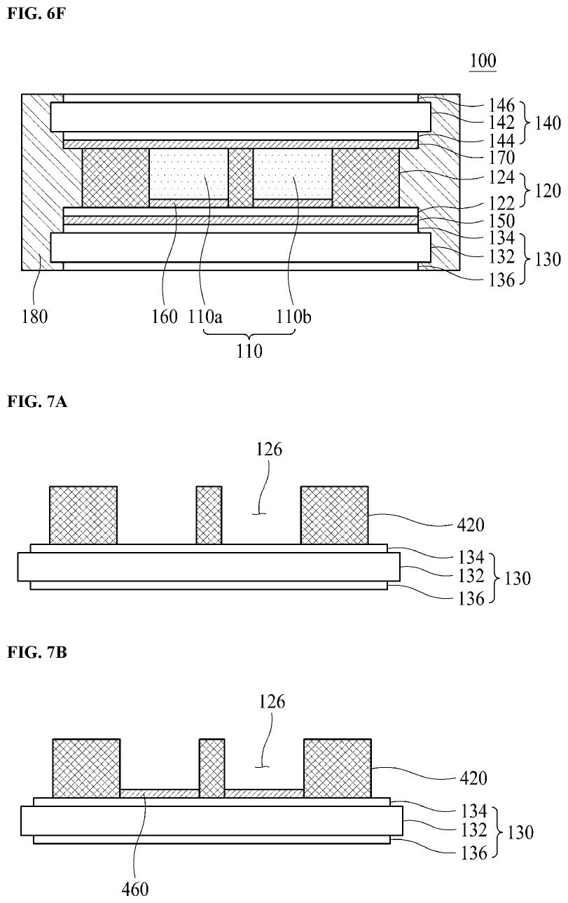

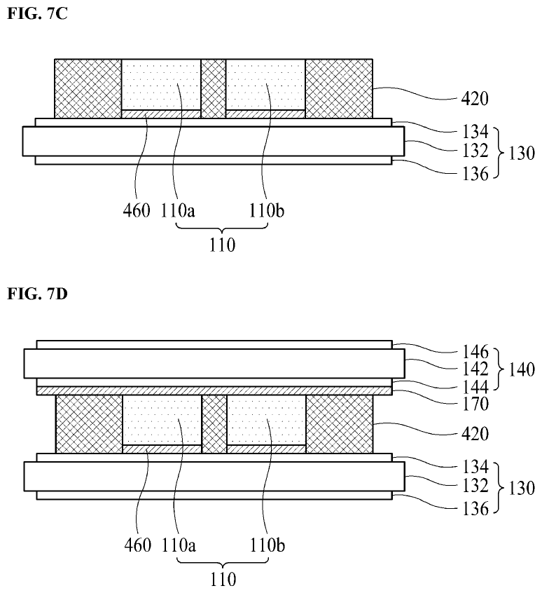

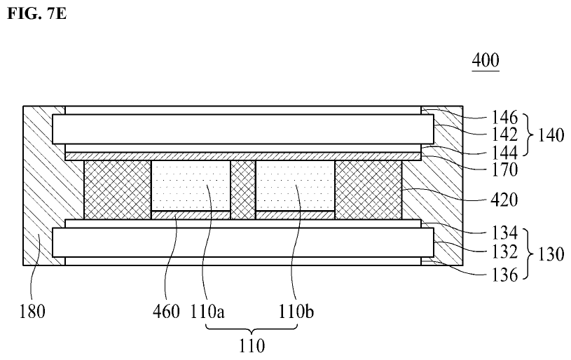

Hereinafter, a method for manufacturing a semiconductor module with a double-sided heat dissipation structure according to the present invention will be described with reference to FIGS. 6 and 7.

FIGS. 6A to 6F are schematic process cross-sectional views showing a method of manufacturing a semiconductor module with a double-sided heat dissipation structure according to the first embodiment of the present invention.

First, as shown in FIG. 6A, the guide stack 124 with the opening area 126 for mounting the semiconductor die 110 may be formed on the base plate 122 to manufacture the guide assembly 120.

In one embodiment, the guide stack 124 may be formed of EMC (Epoxy Mold Compound). According to this embodiment, the guide stack 124 may be formed on the base plate 122 using a molding technique. Specifically, after seating the base plate 122 in the cavity of a mold (not shown) in which a pattern for forming the opening area 126 is formed, the guide stack 124 may be formed on the base plate 122 by injecting EMC into the cavity.

In another embodiment, the guide stack 124 may be formed of Fiber Glass.

According to this embodiment, the guide stack 124 may be formed on the base plate 122 using a screen-printing technique. Specifically, a screen (not shown) with a pattern for forming the opening area 126 may be placed on the base plate 122, and a paste containing Fiber Glass may be applied on the screen. After that, the guide stack 124 may be formed by printing the paste on the base plate 122 while moving the squeegee on the screen.

In one embodiment, the number of opening areas 126 formed in the guide stack 124 may be the same as the number of semiconductor dies 110 included in the semiconductor module 100. For example, when the semiconductor module 100 includes six semiconductor dies, six opening areas 126 are formed in the guide stack 124 to mount the six semiconductor dies.

In the above-described embodiment, the base plate 122 may be formed using a copper-based material, and circuit wiring of a predetermined pattern may be patterned on the base plate 122.

Meanwhile, although not shown in the drawing, an opening area (not shown) may be additionally formed in the guide stack 124 to expose a lead frame terminal for electrically connecting the semiconductor die 110 to an external device.

Thereafter, as shown in FIG. 6B, the lower surface of the base plate 122 is coupled to the first heat dissipation substrate 130 using the first adhesive member 150. The first heat dissipation substrate 130 may include a first substrate 132, a first metal wiring layer 134, and a first heat dissipation metal layer 136, and the lower surface of the base plate 122 is coupled to the first metal wiring layer 134 through the first adhesive member 150. In one embodiment, the first adhesive member 150 may be made of a conductive material, for example, a Sn—Ag series or Ag series material.

Thereafter, as shown in FIG. 6C, after forming the second adhesive member 160 in the area exposed by the opening area 126 of the base plate 122, the semiconductor die 110 may be mounted within the opening area 126 as shown in FIG. 6D. In one embodiment, the second adhesive member 160 may be formed of the same conductive material as the first adhesive member 150. For example, the second adhesive member 160 may be made of Sn—Ag series or Ag series material.

The semiconductor die 110 may include a power semiconductor device such as a GTO, IGBT, or MOSFET, or may include a semiconductor device such as a diode.

In one embodiment, when the semiconductor die 110 is mounted, among the plurality of semiconductor dies 110, the first semiconductor die 110a and the second semiconductor die 110b may be mounted so that electrode arrangement directions are opposite to each other. For example, the first semiconductor die 110a may be arranged so that the first electrode faces the second heat dissipation substrate 140 and the second electrode faces the first heat dissipation substrate 130, and the second semiconductor die 110b has a first electrode facing toward the first heat dissipation substrate 130, the second electrode may be arranged to face the second heat dissipation substrate 140. At this time, the first electrode may include a gate electrode and a source electrode, and the second electrode may include a drain electrode.

Through this arrangement, the first electrode 210 of the first semiconductor die 110a and the second electrode 230 of the second semiconductor die 110b may be electrically connected to connect the first and second semiconductor die 110a and 110b to each other in series.

In another embodiment, each semiconductor die 110 may be mounted so that all the same electrodes face the same direction.

Afterwards, as shown in FIG. 6E, the second heat dissipation substrate 140 may be attached to the semiconductor die 110 and the guide stack 124 using the third adhesive member 170. The second heat dissipation substrate 140 may include a second substrate 142, a second metal wiring layer 144, and a second heat dissipation metal layer 146, and the second metal wiring layer 144 may be coupled to the semiconductor die 110 and the guide stack 124 through the third adhesive member 170. At this time, a predetermined circuit wiring pattern may be formed on the second metal wiring layer 144.

In the above-described embodiment, the first and second metal wiring layers 134 and 144 and the first and second heat dissipation metal layers 136 and 146 may be made of copper-based metal. According to this embodiment, the first and second heat dissipation substrates 130 and 140 may be formed using any one of the Direct Bonded Copper (DBC) method, the Active Material Brazing (AMB) method, and the Direct Plating Copper (DPC) method.

Afterwards, as shown in FIG. 6F, the molding member 180 may be injected into the space between the first heat dissipation substrate 130 and the second heat dissipation substrate 140. The molding member 180 may be EMC. The molding member 180 may increase the insulation distance between the first and second heat dissipation substrates 130 and 140, and protect the semiconductor die 110 from oxidation materials, and can perform the function of fixing the semiconductor die 110.

In this way, according to the present invention, it is only necessary to couple the guide assembly 120 to the first heat dissipation substrate 130 and then mount the plurality of semiconductor dies 110 in the opening area 126 of the guide assembly 120, not only does it become easier to align the semiconductor dies 110, but also process control becomes easier when manufacturing a semiconductor module.

FIGS. 7A to 7E are schematic process cross-sectional views showing a method of manufacturing a semiconductor module with a double-sided heat dissipation structure according to the second embodiment of the present invention.

First, as shown in FIG. 7A, the guide stack 420 having the opening area 126 for mounting semiconductor dies 110a to 110b may be formed on the first heat dissipation substrate 130.

In one embodiment, the guide stack 420 may be formed of EMC. According to this embodiment, the guide stack 420 may be formed on the first heat dissipation substrate 130 using a molding technique. Specifically, after seating the first heat dissipation substrate 130 in the cavity of a mold (not shown) in which a pattern for forming the opening area 126 is formed, the guide stack 420 may be formed on the first heat dissipation substrate 130 by injecting EMC into the cavity.

In another embodiment, the guide stack 420 may be formed of Glass Fiber.

According to this embodiment, the guide stack 420 may be formed on the first heat dissipation substrate 130 using a screen-printing technique. Specifically, a screen with a pattern for forming the opening area 126 may be placed on the first heat dissipation substrate 130, and a paste containing glass fiber may be applied on the screen. Thereafter, the guide stack 420 may be formed by printing the paste on the first heat dissipation substrate 130 while moving the squeegee on the screen.

Afterwards, as shown in FIG. 7B, after forming the second adhesive member 460 on the first heat dissipation substrate 130 corresponding to the opening area 126, as shown in FIG. 7C, the semiconductor die 110 may be mounted within the opening area 126. Except that the semiconductor die 110 is mounted on the first heat dissipation substrate 130 through the second adhesive member 460, the process shown in FIGS. 7B and 7C may be the same as the process shown in FIG. 6C, so specific explanation may be omitted.

Thereafter, as shown in FIG. 7D, the second heat dissipation substrate 140 may be attached to the semiconductor die 110 and the guide stack 420 using the third adhesive member 170. Thereafter, as shown in FIG. 7E, the molding member 180 may be injected into the space between the first heat dissipation substrate 130 and the second heat dissipation substrate 140. Since the process shown in FIGS. 7D and 7E may the same as the process shown in FIGS. 6E and 6F, detailed description may be omitted.

Those skilled in the art to which the present invention pertains will understand that the above-described present invention can be implemented in other specific forms without changing its technical idea or essential features.

Therefore, the embodiments described above should be understood in all respects as illustrative and not restrictive. The scope of the present invention is indicated by the claims described below rather than the detailed description above, and all changes or modified forms derived from the meaning and scope of the claims and their equivalent concepts should be construed as being included in the scope of the present invention.

What is claimed is:

1. A semiconductor module having a double-sided heat dissipation structure, comprising:
a first heat dissipation substrate and a second heat dissipation substrate arranged to face each other;
a guide stack disposed between the first heat dissipation substrate and the second heat dissipation substrate, and having an opening area for mounting a semiconductor die in a pattern; and
a semiconductor die mounted within the opening area.

2. The semiconductor module according to claim 1, further comprising a base plate on which the guide stack is disposed on a first side, and a second side opposite to the first side is coupled to the first heat dissipation substrate; and
a first adhesive member that couples the second side of the base plate to the first heat dissipation substrate.

3. The semiconductor module according to claim 2, further comprising a second adhesive member disposed on an area of the first surface of the base plate exposed through the opening area to couple the semiconductor die to the first surface of the base plate.

4. The semiconductor module according to claim 2, further comprising a first metal wiring layer in which a circuit wiring of a predetermined shape is disposed in a pattern therein, and which is coupled to the base plate through the first adhesive member, and
wherein the base plate is disposed to have the same pattern as the circuit wiring pattern of the first metal wiring layer.

5. The semiconductor module according to claim 1,
the first heat dissipation substrate comprising:
a first substrate;
a first metal wiring layer disposed on a first surface of the first substrate; and
a first heat dissipation metal layer disposed on a second surface of the first substrate,
wherein the guide stack is coupled to the first metal wiring layer.

6. The semiconductor module according to claim 5, further comprising a second adhesive member disposed in the area of the first metal wiring layer exposed through the opening area and bonding the semiconductor die to the first metal wiring layer.

7. The semiconductor module according to claim 3, wherein the second adhesive member comprises a Sn—Ag series or Ag series adhesive member.

8. The semiconductor module according to claim 1, wherein the guide stack comprises EMC (Epoxy Mold Compound) or Fiber Glass.

9. The semiconductor module according to claim 1, wherein the semiconductor die comprises a plurality of semiconductor dies,
wherein the guide stack includes a plurality of opening areas for mounting the plurality of semiconductor dies.

10. The semiconductor module according to claim 9, wherein a gate electrode and a source electrode electrically isolated from the gate electrode are disposed on the first surface of the semiconductor die, and a drain electrode is disposed on the second surface of the semiconductor die,
wherein among the plurality of semiconductor dies, a first semiconductor die has a first surface coupled to the second heat dissipation substrate and the second surface of first semiconductor die is coupled to the first heat dissipation substrate,
wherein among the plurality of semiconductor dies, a second semiconductor die has a first surface coupled to the first heat dissipation substrate and the second surface of the second semiconductor die is coupled to the second heat dissipation substrate.

11. The semiconductor module according to claim 1, wherein the semiconductor die comprises a power semiconductor device.

12. The semiconductor module according to claim 1, further comprising a molding member injected into a space between the first heat dissipation substrate and the second heat dissipation substrate.

13. The semiconductor module according to claim 1, further comprising a third adhesive member that couples the semiconductor die and the guide stack to the second heat dissipation substrate,
wherein the second heat dissipation substrate comprises:
a second substrate;
a second metal wiring layer disposed on a first surface of the second substrate and coupled to the semiconductor die and the guide stack through the third adhesive member; and
a second heat dissipation metal layer formed on a second surface of the second substrate.

14. The semiconductor module according to claim 1, further comprising the guide stack includes a second opening area exposing a lead frame terminal that electrically connects the semiconductor die to an external device.

15. A method of manufacturing a semiconductor module having a double-sided heat dissipation structure comprising,
manufacturing a guide assembly by forming a guide stack with an opening area for mounting a semiconductor die on a base plate;
coupling a second surface of the base plate to a first heat dissipation substrate;
mounting the semiconductor die on a first surface of the base plate corresponding to the opening area; and
coupling a second heat dissipation substrate on the semiconductor die and the guide stack.

16. The method of manufacturing a semiconductor module according to claim 15,
wherein the step of manufacturing the guide assembly comprising:
seating the base plate in a cavity of a mold in which a pattern for forming the opening area is formed; and
a step of injecting EMC into the cavity to form the guide stack on the base plate.

17. The method of manufacturing a semiconductor module according to claim 15,
wherein the step of manufacturing the guide assembly comprising:
placing a screen with a pattern for forming the opening area on the base plate;
applying a paste containing Fiber glass on the screen; and
forming the guide stack by printing the paste on the base plate while moving a squeegee on the screen.

18. The method of manufacturing a semiconductor module according to claim 15,
wherein the second surface of the base plate is coupled to the first heat dissipation substrate through a first adhesive member, the semiconductor die is bonded to an area of the first surface of the base plate exposed through the opening area through a second adhesive member, and the semiconductor die and the guide stack are coupled to the second heat dissipation substrate through a third adhesive member.

19. A method of manufacturing a semiconductor module having a double-sided heat dissipation structure comprising:
forming a guide stack with an opening area for mounting a semiconductor die on a first heat dissipation substrate;
mounting the semiconductor die on an area of the first heat dissipation substrate exposed by the opening area; and
coupling a second heat dissipation substrate on the semiconductor die and the guide stack.

20. The method of manufacturing a semiconductor module according to claim 15, further comprising a step of injecting a molding member into a space between the first heat dissipation substrate and the second heat dissipation substrate.
